(19) United States
(12) Patent Application Publication
(10) Pub. No.: US 2025/0054828 A1
(43) Pub. Date: Feb. 13, 2025

(54) ELECTRONIC PACKAGE AND MANUFACTURING METHOD THEREOF

(71) Applicant: SILICONWARE PRECISION INDUSTRIES CO., LTD., Taiwan (TW)

(72) Inventors: Wei-Shen HUNG, Taiwan (TW); Hsuan-Jen WANG, Taiwan (TW); Rung-Jeng LIN, Taiwan (TW)

(73) Assignee: SILICONWARE PRECISION INDUSTRIES CO., LTD., Taiwan (TW)

(21) Appl. No.: 18/516,192

(22) Filed: Nov. 21, 2023

(30) Foreign Application Priority Data
Aug. 7, 2023 (TW) 112129597

(51) Int. Cl. H01L 23/367; H01L 21/48; H01L 23/00; H01L 23/31; H01L 23/373

(52) U.S. Cl. CPC H01L 23/367; H01L 21/4871; H01L 23/3107; H01L 23/3736; H01L 24/16; H01L 24/32; H01L 24/73; H01L 2224/16225; H01L 2224/32225; H01L 2224/73204; H01L 2924/301

(57) ABSTRACT

An electronic package and a manufacturing method thereof are provided, in which a supporting structure having a supporting body is disposed on a carrying structure and is in contact with or in proximity to an electronic component, and a barrier structure is disposed on the supporting body, such that the electronic component is exposed from an opening of the barrier structure. Furthermore, a thermal conduction layer is formed on the electronic component exposed from the opening of the barrier structure, and the barrier structure blocks or surrounds the thermal conduction layer on the electronic component, thereby preventing the thermal conduction layer from overflowing.

### BACKGROUND

### 1. Technical Field

The present disclosure relates to a packaging structure, and more particularly, to an electronic package with a barrier structure and a manufacturing method thereof.

### 2. Description of Related Art

With the increasing requirements of the functions and processing speed of electronic products, semiconductor chips as the core components of electronic products need to have higher density electronic components and electronic circuits, thus semiconductor chips will generate a greater amount of heat during operation.

In order to rapidly dissipate the heat generated by semiconductor chips to the outside, a heat sink or a heat spreader is usually disposed in a semiconductor package in the industry, so as to bond the heat sink to the inactive surface of a semiconductor chip via a thermal interface material (TIM) layer, and the top sheet of the heat sink is exposed from encapsulation colloid or directly exposed to atmosphere, so that the heat generated by the semiconductor chip can be dissipated via the TIM layer and the heat sink.

As shown in FIG. 1, in the manufacturing method of a conventional semiconductor package 1, firstly, a semiconductor chip 11 is disposed on a packaging substrate 10 via an active surface 11a of the semiconductor chip 11 by means of flip-chip bonding (i.e., via conductive bumps 111 and an underfill 112), then a heat sink 13 is bonded onto an inactive surface 11b of the semiconductor chip 11 via a top sheet 131 of the heat sink 13 by a thermal interface material (TIM) layer 12, and supporting legs 132 of the heat sink 13 are disposed on the packaging substrate 10 via an adhesive layer 14. Next, an encapsulation molding operation is carried out, so that the encapsulation colloid (not shown) covers the semiconductor chip 11 and the heat sink 13, and the top sheet 131 of the heat sink 13 is exposed from the encapsulation colloid.

As the semiconductor package 1 is in operation, the heat generated by the semiconductor chip 11 will be conducted to the top sheet 131 of the heat sink 13 via the inactive surface 11b of the semiconductor chip 11 and the TIM layer 12 so as to be dissipated to outside of the semiconductor package 1.

However, in the conventional semiconductor package 1, the TIM layer 12 will be in liquid state with fluidity after high temperature melting in the reflow operation, thus the TIM layer 12 cannot be fixed on the inactive surface 11b of the semiconductor chip 11 and there is an overflow issue, such that in sequence according to an overflow direction 15 (e.g., from top to bottom) the TIM layer 12 will overflow to side surfaces of the semiconductor chip 11, the underfill 112 and components (not shown) on the packaging substrate 10, thereby causing adverse effects (e.g., electrical short circuit).

Moreover, if colloid (such as an insulating colloid) is used to directly surround the TIM layer 12 that is in the liquid or fluid state, gas will be unable to exhaust. As a result, bubbles or gas (e.g., air) at the TIM layer 12 which is surrounded by the colloid (such as an insulating colloid) cannot be exhausted to the outside.

Therefore, how to overcome various problems of the prior art has become an urgent issue to be overcome in the industry at present.

### SUMMARY

In light of the various shortcomings of the prior art, the present disclosure provides an electronic package, which includes: a carrying structure; an electronic component disposed on the carrying structure; a supporting structure having a supporting body and disposed on the carrying structure, wherein the supporting body of the supporting structure is in contact with or in proximity to the electronic component; a barrier structure having an opening and disposed on the supporting body of the supporting structure, wherein the electronic component is exposed from the opening of the barrier structure; and a thermal conduction layer formed on the electronic component exposed from the opening of the barrier structure, wherein the thermal conduction layer on the electronic component is blocked or surrounded by the barrier structure.

The present disclosure also provides a method of manufacturing an electronic package, the method comprises: disposing an electronic component on a carrying structure; disposing a supporting structure having a supporting body on the carrying structure, wherein the supporting body of the supporting structure is in contact with or in proximity to the electronic component; disposing a barrier structure having an opening on the supporting body of the supporting structure, wherein the electronic component is exposed from the opening of the barrier structure; and forming a thermal conduction layer on the electronic component exposed from the opening of the barrier structure, wherein the thermal conduction layer on the electronic component is blocked or surrounded by the barrier structure.

In the aforementioned electronic package and method, the supporting structure further has at least one supporting leg, and the supporting leg of the supporting structure extends downward from an edge of the supporting body and is bonded to the carrying structure. The supporting structure is a heat dissipation structure, and the supporting body of the supporting structure is made of a heat dissipation material.

In the aforementioned electronic package and method, the barrier structure further has an exhaust channel, and the exhaust channel is disposed outside a distribution area of the electronic component and surrounds a periphery of a distribution area of the thermal conduction layer. Two ends of the exhaust channel are respectively provided with an exhaust port and an outlet in communication with the exhaust port, and the exhaust port of the exhaust channel is in communication with the opening and the outlet. The exhaust channel comprises at least one bend, and a width of the exhaust channel is at least 1 mm.

In the aforementioned electronic package and method, the thermal conduction layer is made of a liquid metal, and the liquid metal on the electronic component is blocked or surrounded by the opening of the barrier structure.

In the aforementioned electronic package and method, the electronic package further comprises a barrier body. The electronic component and the supporting body of the supporting structure have a gap therebetween, and the barrier body is formed in the gap between the electronic component and the supporting body of the supporting structure and blocks the thermal conduction layer. The barrier body surrounds side surfaces of the electronic component, and the barrier body and the barrier structure commonly block the thermal conduction layer on the electronic component.

In the aforementioned electronic package and method, the electronic package further comprises a heat sink disposed on the barrier structure and the thermal conduction layer, wherein the thermal conduction layer is between the electronic component and the heat sink.

As can be seen from the above, in the electronic package and the manufacturing method thereof according to the present disclosure, the barrier structure with an opening is disposed on the supporting body of the supporting structure, and the thermal conduction layer (such as liquid metal) is formed on the electronic component exposed from the opening of the barrier structure, such that the thermal conduction layer on the electronic component is effectively blocked or surrounded by the barrier structure to prevent overflowing.

Meanwhile, the exhaust channel of the barrier structure of the present disclosure can surround the periphery of the distribution area of the thermal conduction layer (such as liquid metal), and the exhaust channel with exhaust function can effectively discharge bubbles or gas (such as air) at the opening of the barrier structure or the thermal conduction layer.

Moreover, the barrier body and the barrier structure of the present disclosure can commonly block the thermal conduction layer on the electronic component, so that the barrier body and the barrier structure can commonly prevent the thermal conduction layer from overflowing to the component on the carrying structure, thereby avoiding adverse effects (such as electrical short circuit).

Furthermore, the heat sink of the present disclosure can be disposed (laminated) on the barrier structure and the thermal conduction layer, so that the heat generated from the electronic component can be rapidly dissipated by the heat sink, and bubbles or gas (such as air) at the opening of the barrier structure or the thermal conduction layer can also be effectively discharged via the exhaust channel.

### BRIEF DESCRIPTION OF THE DRAWINGS

FIG. 1 is a schematic cross-sectional view of a conventional semiconductor package.

FIG. 2, FIG. 3, FIG. 4A, FIG. 5A and FIG. 6 are schematic cross-sectional views illustrating a method of manufacturing an electronic package of the present disclosure, wherein FIG. 4B and FIG. 5B are respectively schematic top views of FIG. 4A and FIG. 5A.

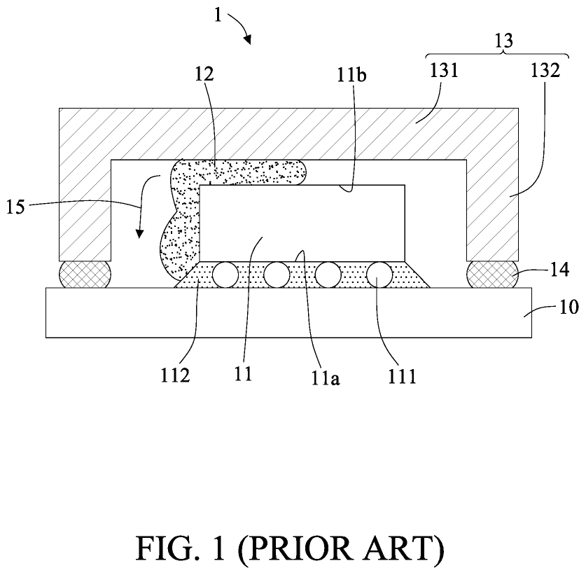

### DETAILED DESCRIPTION

The following describes the implementation of the present disclosure with examples. Those familiar with the art can easily understand the other advantages and effects of the present disclosure from the content disclosed in this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “on,” “below,” “one,” “a,” “first,” “second,” and the like are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

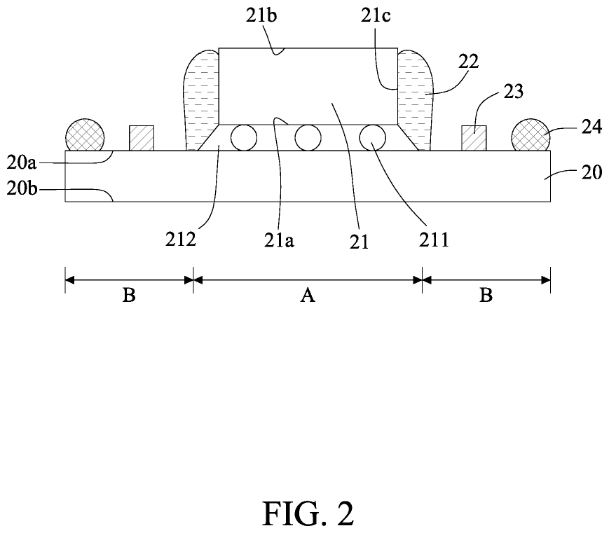

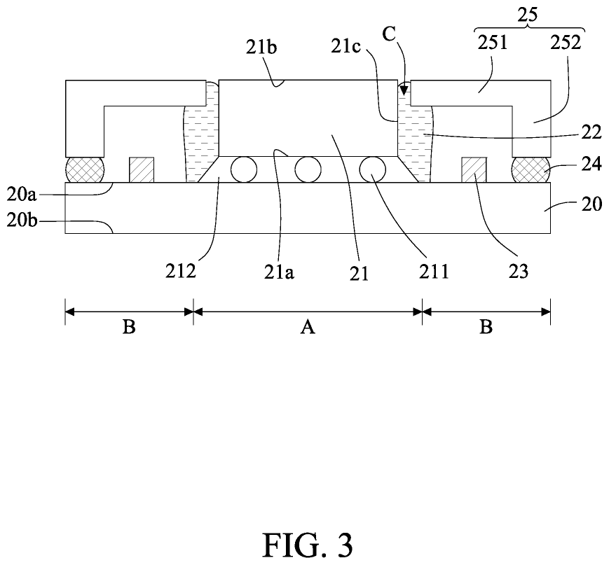

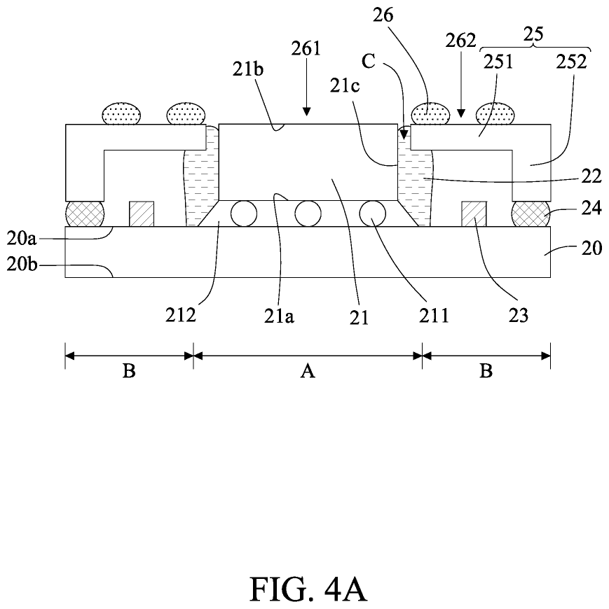

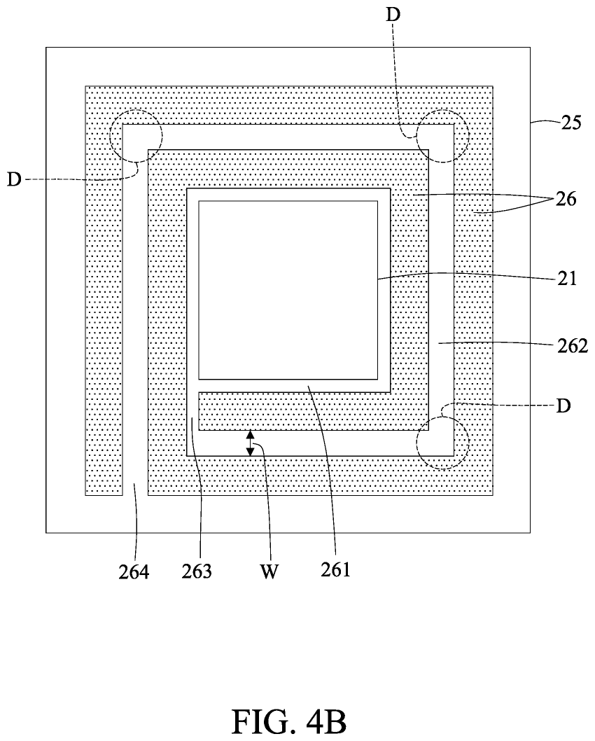

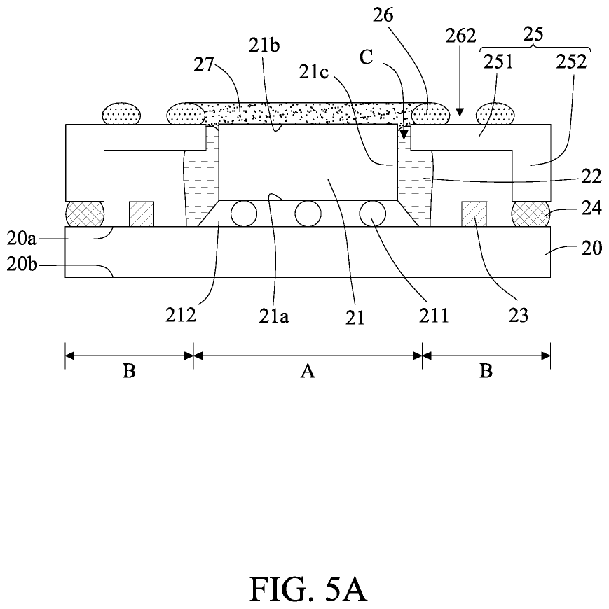

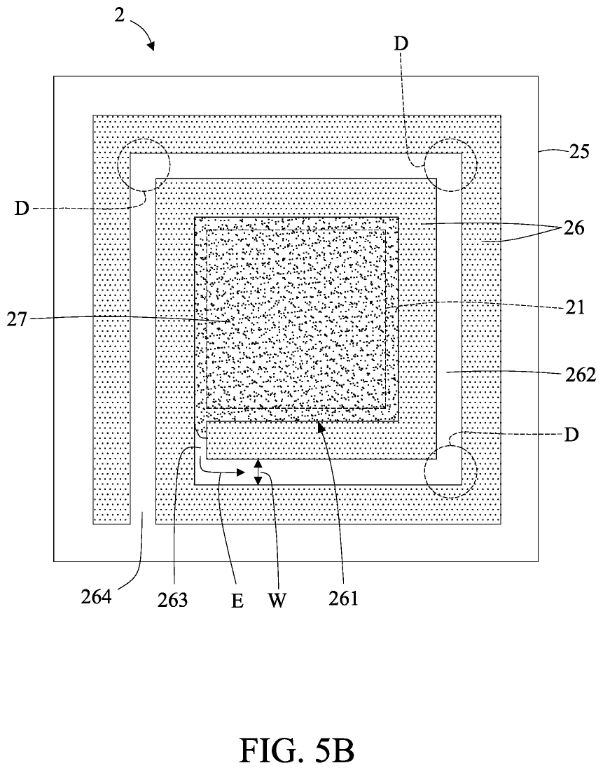

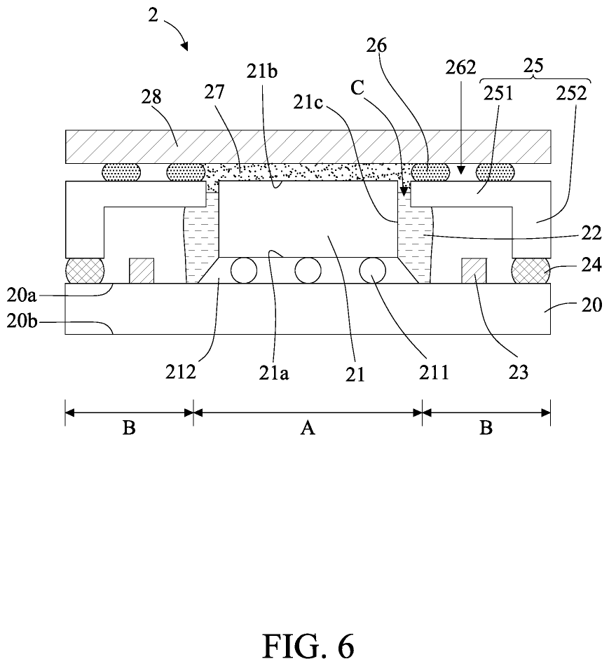

FIG. 2, FIG. 3, FIG. 4A, FIG. 5A and FIG. 6 are schematic cross-sectional views illustrating a method of manufacturing an electronic package 2 of the present disclosure, wherein FIG. 4B and FIG. 5B are respectively schematic top views of FIG. 4A and FIG. 5A.

As shown in FIG. 2, a carrying structure 20 is provided and has a first side 20a (e.g., an upper side) and a second side 20b (e.g., a lower side) opposing the first side 20a, and at least one (or a plurality of) electronic component(s) 21 is disposed on the first side 20a of the carrying structure 20. In the present disclosure, the phrase “at least one” means one or more (such as one, two, three, or more than three), and the phrase “a plurality of” means two or more (such as two, three, five, ten, or more than ten).

In an embodiment, the carrying structure 20 can be a packaging substrate with a core layer and a circuit portion, or a coreless circuit structure. Alternatively, the carrying structure 20 can comprise at least one dielectric layer and a circuit layer bonded to the dielectric layer, such as a fan-out type redistribution layer (RDL). For instance, the first side 20a of the carrying structure 20 can be used as the chip placement side for carrying the electronic component 21, and the second side 20b of the carrying structure 20 can be used as the ball placement side for sequentially connecting solder balls (such as solder balls made with tin or the like) and the electronic devices (such as circuit boards).

It can be understood that the carrying structure 20 can also be other types of carrying unit for carrying the electronic component 21 (e.g., chip), such as a lead frame, a wafer, a silicon interposer, or other types of plate body with metal routings, but the present disclosure is not limited to as such.

In an embodiment, the electronic component 21 can be an active element, a passive element, or a combination of the active element and the passive element. For example, the active element is a semiconductor chip, etc., and the passive element is a resistor, a capacitor, or an inductor, etc.

In an embodiment, the electronic component 21 can be a semiconductor chip and has an active surface 21a and an inactive surface 21b opposing the active surface 21a. A plurality of electrode pads (not shown) can be formed on the active surface 21a of the electronic component 21, so that the plurality of electrode pads can be bonded with and electrically connected to the circuit layer of the carrying structure 20 in a flip-chip manner via a plurality of conductive bumps 211 made of such as solder material, and then an encapsulation layer such as an underfill 212 is filled and formed between the first side 20a of the carrying structure 20 and the active surface 21a of the electronic component 21 to cover the plurality of conductive bumps 211.

In other embodiments, the electronic component 21 can also be electrically connected to the circuit layer of the carrying structure 20 in a wire-bonding manner by a plurality of solder wires (not shown); alternatively, the electronic component 21 can be directly in contact with the circuit layer of the carrying structure 20.

It can be understood that there are various ways for the electronic component 21 to be electrically connected to the carrying structure 20, and the electronic component 21 with the required type and quantity can be arranged on the carrying structure 20 without being limited.

In an embodiment, the first side 20a of the carrying structure 20 can be defined with a chip mounting region A and a peripheral region B, so the electronic component 21 is disposed on the chip mounting region A of the first side 20a of the carrying structure 20, and at least one (or a plurality of) component(s) 23 (such as active element/passive element) and an adhesive layer 24 are respectively disposed on the peripheral region B of the first side 20a of the carrying structure 20, so that the component 23 is electrically connected to the circuit layer (not shown) of the carrying structure 20.

Moreover, as shown in FIG. 2, a barrier body 22 is formed around the electronic component 21 to surround side surfaces 21c of the electronic component 21, or the barrier body 22 can be further formed around the underfill 212 to surround side surfaces of the underfill 212, or the barrier body 22 can be even further formed on part of the first side 20a of the carrying structure 20.

In an embodiment, the barrier body 22 can be made of insulating material (such as insulating colloid), the component 23 can be various types of components such as an active element or a passive element, and the adhesive layer 24 can be made of heat dissipation material (such as heat dissipation colloid) or insulating material (such as insulating colloid), and the component 23 is located between the barrier body 22 and the adhesive layer 24 without being in contact with the barrier body 22 and the adhesive layer 24.

As shown in FIG. 3, one supporting structure 25 is disposed on the peripheral region B of the first side 20a of the carrying structure 20, and the supporting structure 25 has one supporting body 251 and at least one (e.g., a plurality of) supporting leg(s) 252. The supporting body 251 of the supporting structure 25 can be in contact with or in proximity to the side surfaces 21c of the electronic component 21, the supporting body 251 can also be in contact with or bonded to the barrier body 22, and the supporting leg 252 of the supporting structure 25 can extend downward from the edge of the supporting body 251 to be bonded to the carrying structure 20.

In an embodiment, the supporting leg 252 of the supporting structure 25 can be bonded onto the carrying structure 20 via the adhesive layer 24. For instance, the adhesive layer 24 is firstly formed on the first side 20a of the carrying structure 20 in a dispensing manner, so that the adhesive layer 24 is located at a periphery of the component 23 (such as a passive element), and then the supporting leg 252 of the supporting structure 25 is bonded onto the adhesive layer 24 to have the supporting structure 25 fixed on the carrying structure 20. Alternatively, the adhesive layer 24 is not formed on the carrying structure 20 until the supporting structure 25 is disposed on the carrying structure 20, and then the supporting leg 252 is bonded on the carrying structure 20 via the adhesive layer 24.

In an embodiment, the supporting structure 25 can be a heat dissipation structure, and both the supporting body 251 and the supporting leg 252 can be made of heat dissipation material (such as metal material), such that the heat dissipation performance of the electronic package 2 or the electronic component 21 can be improved via the supporting body 251 and the supporting leg 252 of the supporting structure 25. However, in other embodiments, the supporting body 251 and the supporting leg 252 of the supporting structure 25 can also be made of insulating material.

In an embodiment, a gap C is formed between the electronic component 21 and the supporting body 251 of the supporting structure 25, and the barrier body 22 can be interposed in the gap C between the electronic component 21 and the supporting body 251 of the supporting structure 25. In other embodiments, the barrier body 22 may not be provided, and the supporting body 251 of the supporting structure 25 can be directly in contact with and abutted against the side surfaces 21c of the electronic component 21.

As shown in FIG. 4A and FIG. 4B, a barrier structure 26 is disposed on the supporting body 251 of the supporting structure 25. The barrier structure 26 has an opening 261 and an exhaust channel 262 in communication with the opening 261, and the electronic component 21 (such as the inactive surface 21b) is exposed from the opening 261 of the barrier structure 26. Two ends of the exhaust channel 262 of the barrier structure 26 are respectively provided with an exhaust port 263 and an outlet 264 in communication with the exhaust port 263, and the exhaust port 263 of the exhaust channel 262 is in communication with the opening 261 of the barrier structure 26.

In an embodiment, the shape of the barrier structure 26 can be approximately ring-shaped, O-shaped, square-shaped, double square-shaped, etc., and the shape of the exhaust channel 262 of the barrier structure 26 can be approximately ring-shaped, C-shaped, O-shaped, square-shaped, etc.

In an embodiment, a width W of the exhaust channel 262 of the barrier structure 26 can be at least 1 mm. The barrier structure 26 can be made of heat dissipation material (such as metal material), such that the heat dissipation performance of the electronic package 2 (see FIG. 5A) or the electronic component 21 can be improved via the barrier structure 26. However, in other embodiments, the barrier structure 26 can also be made of insulating material.

In an embodiment, the exhaust channel 262 of the barrier structure 26 can comprise at least one (such as a plurality of) bend(s) D, and the bend D of the exhaust channel 262 can present as a right-angle bend, an oblique bend, or a rounded bend, etc.

In an embodiment, the exhaust channel 262 of the barrier structure 26 can be disposed outside a distribution area of the electronic component 21, which means that the exhaust channel 262 of the barrier structure 26 is not disposed within the distribution area of the electronic component 21 (such as on the inactive surface 21b), and the barrier structure 26 for example is disposed on the peripheral region B.

As shown in FIG. 5A and FIG. 5B, a thermal conduction layer 27 is formed on the electronic component 21 (such as the inactive surface 21b) exposed from the opening 261 of the barrier structure 26, such that the thermal conduction layer 27 on the electronic component 21 (such as the inactive surface 21b) is blocked or surrounded by the barrier structure 26. For instance, in the subsequent processes (see FIG. 6), a heat sink 28 is disposed (laminated) on the barrier structure 26 and the thermal conduction layer 27, such that bubbles or gas (such as air) at the opening 261 of the barrier structure 26 or the thermal conduction layer 27 can be effectively discharged to the outside of the outlet 264 via the exhaust channel 262 according to an exhaust direction E.

In an embodiment, the barrier body 22 can surround the side surfaces 21c of the electronic component 21, and the barrier body 22 and the barrier structure 26 can commonly block the thermal conduction layer 27 on the electronic component 21, such that the barrier body 22 and the barrier structure 26 can commonly prevent the thermal conduction layer 27 from overflowing to the side surfaces 21c of the electronic component 21 and the component 23 on the carrying structure 20, thereby avoiding adverse effects (such as electrical short circuit).

In an embodiment, the barrier body 22 can be formed in the gap C between the electronic component 21 and the supporting body 251 of the supporting structure 25, so that the barrier body 22 can block the thermal conduction layer 27 or prevent the thermal conduction layer 27 from overflowing to the side surfaces 21c of the electronic component 21 and the component 23 on the carrying structure 20 through the gap C, thereby avoiding adverse effects (such as electrical short circuit).

In an embodiment, the barrier structure 26 (such as the opening 261) can block or surround the thermal conduction layer 27, so that the barrier structure 26 (such as the opening 261) can block the thermal conduction layer 27 or prevent the thermal conduction layer 27 from overflowing to the side surfaces 21c of the electronic component 21 and the component 23 on the carrying structure 20, thereby avoiding adverse effects (such as electrical short circuit).

In an embodiment, the exhaust channel 262 of the barrier structure 26 can surround a periphery of a distribution area of the thermal conduction layer 27 (such as liquid metal), and the exhaust channel 262 of the barrier structure 26 with exhaust function can effectively discharge bubbles or gas (such as air) at the opening 261 of the barrier structure 26 or the thermal conduction layer 27.

In an embodiment, the thermal conduction layer 27 can be a thermal interface material (TIM) layer made of liquid metal. For instance, the thermal conduction layer 27 can be made of liquid metal such as solder material and has a high thermal conductivity (such as 86 W/mK), so that the thermal conduction layer 27 cannot pass through the exhaust channel 262 of the barrier structure 26 due to the surface tension, but bubbles or gas at the opening 261 of the barrier structure 26 or the thermal conduction layer 27 can be discharged to the outside via the exhaust channel 262.

As shown in FIG. 6, the heat sink 28 is disposed (laminated) on the barrier structure 26 and the thermal conduction layer 27, so that the heat generated from the electronic component 21 can be rapidly dissipated by the heat sink 28, and bubbles or gas (such as air) at the opening 261 of the barrier structure 26 or the thermal conduction layer 27 can also be effectively discharged to the outside of the outlet 264 via the exhaust channel 262.

In an embodiment, the heat sink 28 can be a heat dissipation structure or a heat dissipation sheet, etc., and the heat sink 28 can be made of heat dissipation material (such as metal material). For instance, the heat sink 28 can be a sheet-type heat sink, and the heat sink 28 can laminate the thermal conduction layer 27 (such as liquid metal), so that the thermal conduction layer 27 is between the electronic component 21 and the heat sink 28.

Then, a plurality of conductive components (not shown) such as metal pillars such as copper pillars, metal bumps covered with insulating blocks, solder balls, solder balls with copper core balls or other conductive configurations can be disposed on the second side 20b of the carrying structure 20, thereby obtaining the electronic package 2 of the present disclosure. In the subsequent process, the electronic package 2 can be connected to an electronic device (not shown) such as a circuit board via the plurality of conductive components.

The present disclosure further provides an electronic package 2, the electronic package 2 comprises: a carrying structure 20; an electronic component 21 disposed on the carrying structure 20; a supporting structure 25 having a supporting body 251 and disposed on the carrying structure 20, wherein the supporting body 251 of the supporting structure 25 is in contact with or in proximity to the electronic component 21; a barrier structure 26 having an opening 261 and disposed on the supporting body 251 of the supporting structure 25, wherein the electronic component 21 is exposed from the opening 261 of the barrier structure 26; and a thermal conduction layer 27 formed on the electronic component 21 exposed from the opening 261 of the barrier structure 26, wherein the thermal conduction layer 27 on the electronic component 21 is blocked or surrounded by the barrier structure 26.

In an embodiment, the supporting structure 25 further has at least one supporting leg 252, and the supporting leg 252 of the supporting structure 25 extends downward from the edge of the supporting body 251 and is bonded to the carrying structure 20. The supporting structure 25 can be a heat dissipation structure, and both the supporting body 251 of the supporting structure 25 and the supporting leg 252 of the supporting structure 25 are made of heat dissipation material.

In an embodiment, the barrier structure 26 can have an exhaust channel 262, and the exhaust channel 262 is disposed outside a distribution area of the electronic component 21 and surrounds a periphery of a distribution area of the thermal conduction layer 27. Two ends of the exhaust channel 262 of the barrier structure 26 are respectively provided with an exhaust port 263 and an outlet 264 in communication with the exhaust port 263, and the exhaust port 263 of the exhaust channel 262 is in communication with the opening 261 and the outlet 264. The exhaust channel 262 of the barrier structure 26 comprises at least one (such as a plurality of) bend(s) D, and a width W of the exhaust channel 262 of the barrier structure 26 is at least 1 mm.

In an embodiment, the thermal conduction layer 27 can be made of liquid metal, such that the liquid metal on the electronic component 21 is blocked or surrounded by the opening 261 of the barrier structure 26.

In an embodiment, the electronic package 2 can also comprise a barrier body 22. A gap C is formed between the electronic component 21 and the supporting body 251 of the supporting structure 25, and the barrier body 22 is formed in the gap C between the electronic component 21 and the supporting body 251 of the supporting structure 25 to block the thermal conduction layer 27. The barrier body 22 surrounds side surfaces 21c of the electronic component 21, and the barrier body 22 and the barrier structure 26 commonly block the thermal conduction layer 27 on the electronic component 21.

In an embodiment, the electronic package 2 can further comprise a heat sink 28, the heat sink 28 is disposed (laminated) on the barrier structure 26 and the thermal conduction layer 27, and the thermal conduction layer 27 is between the electronic component 21 and the heat sink 28, such that bubbles or gas (such as air) at the opening 261 of the barrier structure 26 or the thermal conduction layer 27 can be discharged via the exhaust channel 262.

To sum up, the electronic package and the manufacturing method thereof of the present disclosure have at least following features, advantages, or technical effects.

1. The present disclosure can arrange the barrier structure having an opening on the supporting body of the supporting structure, and form a thermal conduction layer (such as liquid metal) on the electronic component exposed from the opening of the barrier structure, such that the thermal conduction layer on the electronic component is effectively blocked or surrounded by the barrier structure to prevent overflowing.

2. The barrier structure (such as the opening) of the present disclosure can block or surround the thermal conduction layer, so that the barrier structure (such as the opening) can block the thermal conduction layer or prevent the thermal conduction layer from overflowing to the side surfaces of the electronic component and the component on the carrying structure, thereby avoiding adverse effects (such as electrical short circuit).

3. The exhaust channel of the barrier structure of the present disclosure can surround the periphery of the distribution area of the thermal conduction layer (such as liquid metal), and the exhaust channel with exhaust function can effectively discharge bubbles or gas (such as air) at the opening of the barrier structure or the thermal conduction layer.

4. The barrier body of the present disclosure can be formed in the gap between the electronic component and the supporting body of the supporting structure, so that the barrier body can block the thermal conduction layer or prevent the thermal conduction layer from overflowing to the component on the carrying structure through the gap, thereby avoiding adverse effects (such as electrical short circuit).

5. The barrier body and the barrier structure of the present disclosure can commonly block the thermal conduction layer on the electronic component, so that the barrier body and the barrier structure can commonly prevent the thermal conduction layer from overflowing to the component on the carrying structure, thereby avoiding adverse effects (such as electrical short circuit).

6. The supporting structure and/or the barrier structure of the present disclosure can be made of heat dissipation material (such as metal material), such that the heat dissipation performance of the electronic package or the electronic component can be improved via the supporting structure and/or the barrier structure.

7. The heat sink of the present disclosure can be disposed (laminated) on the barrier structure and the thermal conduction layer, so that the heat generated from the electronic component can be rapidly dissipated by the heat sink, and bubbles or gas (such as air) at the opening of the barrier structure or the thermal conduction layer can also be effectively discharged via the exhaust channel.

The above embodiments are set forth to illustrate the principles of the present disclosure and the effects thereof, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
a carrying structure;
an electronic component disposed on the carrying structure;
a supporting structure having a supporting body and disposed on the carrying structure, wherein the supporting body of the supporting structure is in contact with or in proximity to the electronic component;
a barrier structure having an opening and disposed on the supporting body of the supporting structure, wherein the electronic component is exposed from the opening of the barrier structure; and
a thermal conduction layer formed on the electronic component exposed from the opening of the barrier structure, wherein the thermal conduction layer on the electronic component is blocked or surrounded by the barrier structure.

2. The electronic package of claim 1, wherein the supporting structure further has at least one supporting leg, and the supporting leg of the supporting structure extends downward from an edge of the supporting body and is bonded to the carrying structure.

3. The electronic package of claim 1, wherein the supporting structure is a heat dissipation structure, and the supporting body of the supporting structure is made of a heat dissipation material.

4. The electronic package of claim 1, wherein the barrier structure further has an exhaust channel, and the exhaust channel is disposed outside a distribution area of the electronic component and surrounds a periphery of a distribution area of the thermal conduction layer.

5. The electronic package of claim 1, wherein the barrier structure further has an exhaust channel, two ends of the exhaust channel are respectively provided with an exhaust port and an outlet in communication with the exhaust port, and the exhaust port of the exhaust channel is in communication with the opening and the outlet.

6. The electronic package of claim 1, wherein the barrier structure further has an exhaust channel, the exhaust channel comprises at least one bend, and a width of the exhaust channel is at least 1 mm.

7. The electronic package of claim 1, wherein the thermal conduction layer is made of a liquid metal, and the liquid metal on the electronic component is blocked or surrounded by the opening of the barrier structure.

8. The electronic package of claim 1, further comprising a barrier body, wherein the electronic component and the supporting body of the supporting structure have a gap therebetween, and the barrier body is formed in the gap between the electronic component and the supporting body of the supporting structure and blocks the thermal conduction layer.

9. The electronic package of claim 1, further comprising a barrier body surrounding side surfaces of the electronic component, wherein the barrier body and the barrier structure commonly block the thermal conduction layer on the electronic component.

10. The electronic package of claim 1, further comprising a heat sink disposed on the barrier structure and the thermal conduction layer, wherein the thermal conduction layer is between the electronic component and the heat sink.

11. A method of manufacturing an electronic package, comprising:
disposing an electronic component on a carrying structure;
disposing a supporting structure having a supporting body on the carrying structure, wherein the supporting body of the supporting structure is in contact with or in proximity to the electronic component;
disposing a barrier structure having an opening on the supporting body of the supporting structure, wherein the electronic component is exposed from the opening of the barrier structure; and
forming a thermal conduction layer on the electronic component exposed from the opening of the barrier structure, wherein the thermal conduction layer on the electronic component is blocked or surrounded by the barrier structure.

12. The method of claim 11, wherein the supporting structure further has at least one supporting leg, and the supporting leg of the supporting structure extends downward from an edge of the supporting body and is bonded to the carrying structure.

13. The method of claim 11, wherein the supporting structure is a heat dissipation structure, and the supporting body of the supporting structure is made of a heat dissipation material.

14. The method of claim 11, wherein the barrier structure further has an exhaust channel, and the exhaust channel is disposed outside a distribution area of the electronic component and surrounds a periphery of a distribution area of the thermal conduction layer.

15. The method of claim 11, wherein the barrier structure further has an exhaust channel, two ends of the exhaust channel are respectively provided with an exhaust port and an outlet in communication with the exhaust port, and the exhaust port of the exhaust channel is in communication with the opening and the outlet.

16. The method of claim 11, wherein the barrier structure further has an exhaust channel, the exhaust channel comprises at least one bend, and a width of the exhaust channel is at least 1 mm.

17. The method of claim 11, wherein the thermal conduction layer is made of a liquid metal, and the liquid metal on the electronic component is blocked or surrounded by the opening of the barrier structure.

18. The method of claim 11, further comprising forming a barrier body in a gap between the electronic component and the supporting body of the supporting structure to block the thermal conduction layer.

19. The method of claim 11, further comprising forming a barrier body to surround side surfaces of the electronic component, wherein the barrier body and the barrier structure commonly block the thermal conduction layer on the electronic component.

20. The method of claim 11, further comprising disposing a heat sink on the barrier structure and the thermal conduction layer, and the thermal conduction layer is between the electronic component and the heat sink.
